(19) United States
(12) Patent Application Publication
(10) Pub. No.: US 2022/0209041 A1
(43) Pub. Date: Jun. 30, 2022

(54) PHOTODIODE MANUFACTURING METHOD AND PHOTODIODE THEREOF

(71) Applicant: NINGBO ABAX SENSING CO., LTD., Ningbo City (CN)

(72) Inventor: Shuyu LEI, Ningbo City, Zhejiang Province (CN)

(73) Assignee: Ningbo ABAX Sensing Electronic Technology Co., Ltd., Ningbo City (CN)

(21) Appl. No.: 17/604,047

(22) PCT Filed: Oct. 9, 2019
(86) PCT No.: PCT/CN2019/110217

§ 371 Date: Oct. 15, 2021

(30) Foreign Application Priority Data
Apr. 15, 2019 (CN) 201910297257.0

(51) Int. Cl. H01L 31/112; H01L 31/18

(52) U.S. Cl. CPC H01L 31/1129; H01L 31/18

(57) ABSTRACT

A photodiode manufacturing method and a photodiode thereof. The method comprises: doping a second type of material in a first region of an epitaxial layer to form a first doped region; forming a transfer gate on the upper surface of the epitaxial layer, one side of the transfer gate being connected to the first doped region; doping the second type of material in a second region of the epitaxial layer to form a second doped region, the second doped region being connected to the first doped region; and doping the second type of material in a third region of the epitaxial layer to obtain an output region, the other side of the transfer gate being connected to the output region.

### CROSS REFERENCE TO RELATED APPLICATION

The present application claims priority to Chinese Patent Application No. CN201910297257.0, titled “PHOTODIODE MANUFACTURING METHOD AND PHOTODIODE THEREOF”, filed on Apr. 15, 2019 with the Chinese Patent Office, which is incorporated herein by reference in its entirety.

### FIELD

The present disclosure relates to the field of semiconductors, and in particular to a photodiode manufacturing method and a photodiode.

### BACKGROUND

With the development of science and technology, complementary metal oxide semiconductor (CMOS) image sensors have been widely used in various aspects of people's life, for example, in long distance and high precision ranging, high dynamic range imaging, and high frame rate imaging.

In the conventional technology, a CMOS image sensor at least includes: a pixel array, a timing control module, an analog signal processing module, and an analog-to-digital conversion module. In the pixel array, photodiodes may be utilized to achieve photoelectric conversion. FIG. 1 is a schematic structural diagram of a photodiode in the conventional technology. As shown in FIG. 1, the photodiode has a P-type substrate P-sub1. A P-type epitaxial layer P-epi2 is provided on the P-type substrate P-sub1. An N-type doped region PDN3 is provided in a region of the P-type epitaxial layer P-epi2. A clamping layer 6 is provided on a portion of an upper surface of the N-type doped region PDN3. An output terminal FD4 is provided in another region of the P-type epitaxial layer P-epi2. A transmission gate TX5 is formed on an upper surface of the P-type epitaxial layer P-epi2. A lower surface of the transmission gate TX5 is directly connected to the output terminal FD4 and the N-type doped region PDN3. Under this configuration, the photodiode receives a light, the light enters the P-type epitaxial layer P-epi2, and photo-generated electrons are generated in the P-type epitaxial layer P-epi2. The N-type doped region PDN3 attracts the photo-generated electrons, so that the photo-generated electrons generated in the P-type epitaxial layer P-epi2 are stored in the N-type doped region PDN3. In this case, if the transmission gate TX5 is powered on, an inversion layer is formed between the N-type doped region PDN3 and the output terminal FD4. The inversion layer functions as a conductive channel to output the photo-generated electrons in the N-type doped region PDN3 from the output terminal FD4 via the conductive channel itself.

However, it is founded by the inventors of the present disclosure when realizing the above conventional technology that, if the transmission gate TX5 is powered off, the inversion layer releases part of the photo-generated electrons, and the released photo-generated electrons return to the N-type doped region PDN3, so that photo-generated electrons generated in a next photoelectric conversion process are indistinguishable from the photo-generated electrons returning to the N-type doped region PDN3, which results in a poor photoelectric conversion effect of the photodiode.

### SUMMARY

An object of the present disclosure is to provide a photodiode manufacturing method and a photodiode, to solve a problem of a poor photoelectric conversion effect of the photodiode.

In order to achieve the above object, a photodiode manufacturing method is provided in a first aspect of embodiments of the present disclosure. The method includes:

forming an epitaxial layer on a side of a silicon substrate, where the epitaxial layer is doped with a first type of material;

doping a second type of material in a first region of the epitaxial layer to form a first doped region;

forming a transmission gate on an upper surface of the epitaxial layer, where one side of the transmission gate is connected to the first doped region;

doping the second type of material in a second region of the epitaxial layer to form a second doped region, where the second doped region is connected to the first doped region; and

doping the second type of material in a third region of the epitaxial layer to obtain an output region, where the other side of the transmission gate is connected to the output region.

Further, before the second type of material is doped in the first region of the epitaxial layer to form the first doped region, the method further includes: doping the first type of material below the first region to form a first isolation region.

Further, before the transmission gate is formed on the upper surface of the epitaxial layer, the method further includes: doping the first type of material above the second doped region and the first doped region to form a second isolation region. The one side of the transmission gate is connected to the first doped region through the second isolation region.

Further, the second type of material and the first type of material are respectively different types of semiconductor materials, and the semiconductor materials include a P-type semiconductor material and an N-type semiconductor material.

Further, the doping is implemented by an implantation process.

Further, the one side of the transmission gate being connected to the first doped region is implemented by connecting at least half of a lower surface of the transmission gate to the first doped region.

Further, a concentration of the second type of material in the first doped region is higher than a concentration of the second type of material in the second doped region.

Further, an overlapping region exists between the first doped region and the second doped region.

Further, before the second type of material is doped in the first region of the epitaxial layer to form the first doped region, the photodiode manufacturing method further includes: doping the first type of material in a fourth region of the epitaxial layer to form a third isolation region. The output region is disposed in the third isolation region.

Further, the third isolation region is not directly connected to the first doped region.

Further, the process of doping the first type of material in the fourth region of the epitaxial layer to form the third isolation region is performed by implanting the first type of material in the fourth region at least twice. In two successive implantations, an implantation dose and an implantation energy in a later implantation are respectively smaller than those in a previous implantation.

Further, the first isolation region is connected to both the and the second doped region.

Further, after the first transmission gate and the second transmission gate are formed on the upper surface of the epitaxial layer, the photodiode manufacturing method further includes: forming a sidewall on a side surface of the transmission gate; and doping the first type of material between the second isolation region and the second doped region to obtain a fourth isolation region. The third region is located between the second isolation region and the second doped region.

Further, the process of forming the transmission gate on the upper surface of the epitaxial layer includes:

forming a polysilicon gate on the upper surface of the epitaxial layer; and

etching the polysilicon gate to form the transmission gate.

In a second aspect of the embodiments of the present disclosure, a photodiode is provided. The photodiode includes: an epitaxial layer, a first doped region, a transmission gate, a second doped region, and an output region, where

the epitaxial layer is disposed on a silicon substrate, and the epitaxial layer is doped with a first type of material;

the first doped region is disposed in a first region of the epitaxial layer, and the first doped region is doped with a second type of material;

the second doped region is disposed in a second region of the epitaxial layer, the second doped region is doped with the second type of material, and the second doped region is connected to the first doped region;

the transmission gate is disposed on an upper surface of the epitaxial layer, and one side of the transmission gate is connected to the first doped region; and

the output region is disposed in a third region of the epitaxial layer, the output region is doped with the first type of material, and the other side of the transmission gate is connected to the output region.

Further, the photodiode further includes a first isolation region. The first isolation region is disposed below the first region. The first isolation region is doped with the first type of material.

Further, the photodiode further includes a second isolation region. The second isolation region is disposed above the second doped region and the first doped region. The second isolation region is doped with the first type of material. The one side of the transmission gate is connected to the first doped region through the second isolation region.

Further, the second type of material and the first type of material are respectively different types of semiconductor materials. The semiconductor materials include a P-type semiconductor material and an N-type semiconductor material.

Further, at least half of a lower surface of the transmission gate is connected to the first doped region.

Further, a concentration of the second type of material in the first doped region is higher than a concentration of the second type of material in the second doped region.

Further, an overlapping region exists between the first doped region and the second doped region.

Further, the photodiode further includes a third isolation region. The third isolation region is disposed in a fourth region of the epitaxial layer. The third isolation region is doped with the first type of material. The output region is disposed in the third isolation region.

Further, the third isolation region is not directly connected to the first doped region.

Further, the first isolation region is connected to both the and the second doped region.

Further, the photodiode further includes a sidewall and a fourth isolation region. The sidewall is disposed on a side surface of the transmission gate. The fourth isolation region is disposed between the second isolation region and the second doped region. The fourth isolation region is doped with the first type of material.

With the above technical solutions, a photodiode manufacturing method and a photodiode are provided in the present disclosure. The photodiode manufacturing method includes: forming an epitaxial layer on a side of a silicon substrate, where the epitaxial layer is doped with a first type of material; doping a second type of material in a first region of the epitaxial layer to form a first doped region; forming a transmission gate on an upper surface of the epitaxial layer, where one side of the transmission gate is connected to the first doped region; doping the second type of material in a second region of the epitaxial layer to form a second doped region, where the second doped region is connected to the first doped region; and doping the second type of material in a third region of the epitaxial layer to obtain an output region, where the other side of the transmission gate is connected to the output region. With this method, in a case that the transmission gate is powered off, photo-generated electrons released from an inversion layer between the first doped region and the output region can be stored in the first doped region disposed between the second doped region and the transmission gate before flowing back to the second doped region, which prevents the released photo-generated electrons from flowing back to the second doped region, avoids an influence on the photo-generated electrons generated in a next photoelectric conversion process, and further improves the photoelectric conversion effect of the photodiode.

Other features and advantages of the present disclosure are described in detail in the following specific embodiments.

### BRIEF DESCRIPTION OF THE DRAWINGS

The accompanying drawings are given to provide a further understanding of the present disclosure and form a part of this specification. The accompanying drawings, together with the following embodiments, are used to explain the present disclosure, and do not constitute a limitation to the present disclosure. In the accompanying drawings:

FIG. 1 is a schematic structural diagram of a photodiode in the conventional technology;

FIG. 2 is a schematic structural diagram of a photodiode according to an embodiment of the present disclosure;

FIG. 3 is a schematic structural diagram of a photodiode according to another embodiment of the present disclosure;

FIG. 4 is a schematic flowchart of a photodiode manufacturing method according to an embodiment of the present disclosure; and

FIG. 5 is a schematic flowchart of a photodiode manufacturing method according to another embodiment of the present disclosure.

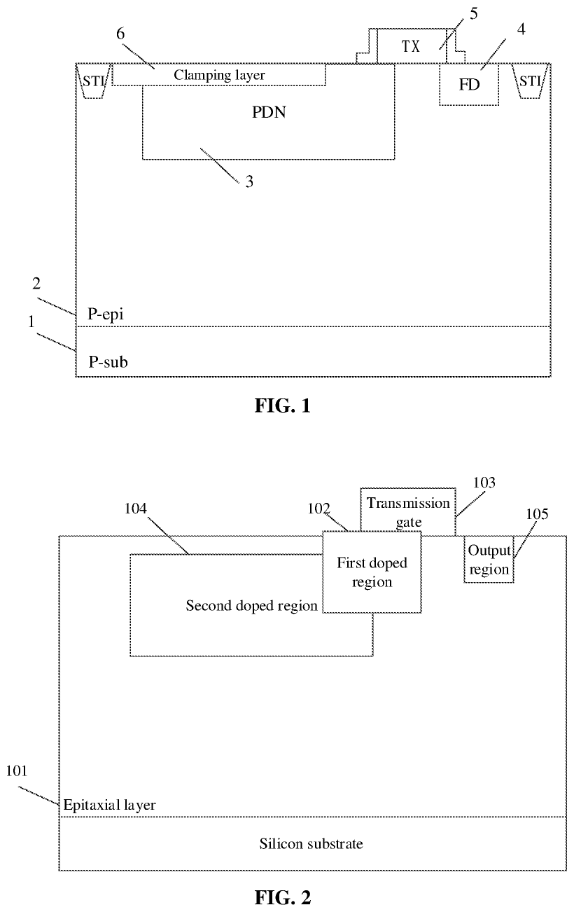

### DETAILED DESCRIPTION OF EMBODIMENTS

Exemplary embodiments are described in detail hereafter, and examples thereof are shown in the accompanying drawings. In the following description related to the accompanying drawings, the same number in different drawings indicates the same or similar elements unless otherwise indicated. Implementations described in the following exemplary embodiments do not represent all implementations consistent with the present disclosure, and merely show examples of devices and methods consistent with some aspects of the present disclosure as detailed in the appended claims.

FIG. 2 is a schematic structural diagram of a photodiode according to an embodiment of the present disclosure. As shown in FIG. 2, the photodiode includes: an epitaxial layer 101, a first doped region 102, a transmission gate 103, a second doped region 4, and an output region 105.

The epitaxial layer 101 is disposed on a silicon substrate. The epitaxial layer 101 is doped with a first type of material.

The first doped region 102 is disposed in a first region of the epitaxial layer 101. The first doped region 102 is doped with a second type of material.

The second doped region 104 is disposed in a second region of the epitaxial layer 101. The second doped region 104 is doped with the second type of material. The second doped region 104 is connected to the first doped region 102.

Preferably, an overlapping region exists between the first doped region 102 and the second doped region 104. A concentration of the second type of material in the first doped region 102 is higher than a concentration of the second type of material in the second doped region 104. In this way, part of electrons can be stored in the overlapping region between the first doped region 102 and the second doped region 104. Furthermore, if the transmission gate 103 is powered off, the overlapping region can store photo-generated electrons released from an inversion layer, which prevents the electrons from injecting back into the second doped region 104 and further avoids an influence on a next photoelectric conversion process, thereby improving the photoelectric conversion efficiency.

The transmission gate 103 is disposed on an upper surface of the epitaxial layer 101. One side of the transmission gate is connected to the first doped region 102.

The output region 105 is disclosed in a third region of the epitaxial layer 101. The output region 105 is doped with the first type of material. The other side of the transmission gate is connected to the output region 105.

Preferably, at least half of a lower surface of the transmission gate is connected to the first doped region 102.

When the photodiode receives a light, the light enters the epitaxial layer 101 to generate photo-generated electrons. The second doped region 104 attracts the photo-generated electrons, so that the photo-generated electrons are attracted into the second doped region 104. Next, the transmission gate is powered on, so that the photo-generated electrons in the second doped region 104 are transmitted to the output region 105 via the first doped region 102 and the inversion layer between the first doped region and the output region 105. Next, if the transmission gate is powered off, the inversion layer between the first doped region 102 and the output region 105 may release the photo-generated electrons, and the released photo-generated electrons flow back to the second doped region 104. By disposing the first doped region 102 between the second doped region 104 and the transmission gate 103, the released photo-generated electrons can be stored in the first doped region 102, which prevents the released photo-generated electrons from flowing back to the second doped region 104, avoids an influence on photo-generated electrons generated in the next photoelectric conversion process, and further improves an efficiency of the photodiode processing the photoelectric conversion.

In this embodiment, the photodiode includes: an epitaxial layer, a first doped region, a transmission gate, a second doped region, and an output region. The epitaxial layer is disposed on a silicon substrate, and the epitaxial layer is doped with a first type of material. The first doped region is disposed in a first region of the epitaxial layer, and the first doped region is doped with a second type of material. The second doped region is disposed in a second region of the epitaxial layer, and the second doped region is doped with the second type of material. The second doped region is connected to the first doped region. The transmission gate is disposed on an upper surface of the epitaxial layer. One side of the transmission gate is connected to the first doped region. The output region is disposed in a third region of the epitaxial layer, and the output region is doped with the first type of material. The other side of the transmission gate is connected to the output region. With this configuration, in the case that the transmission gate is powered off, the photo-generated electrons released from the inversion layer between the first doped region and the output region can be stored in the first doped region disposed between the second doped region and the transmission gate before flowing back to the second doped region, which prevents the released photo-generated electrons from flowing back to the second doped region, avoids the influence on the photo-generated electrons generated in the next photoelectric conversion process, and further improves the photoelectric conversion effect of the photodiode.

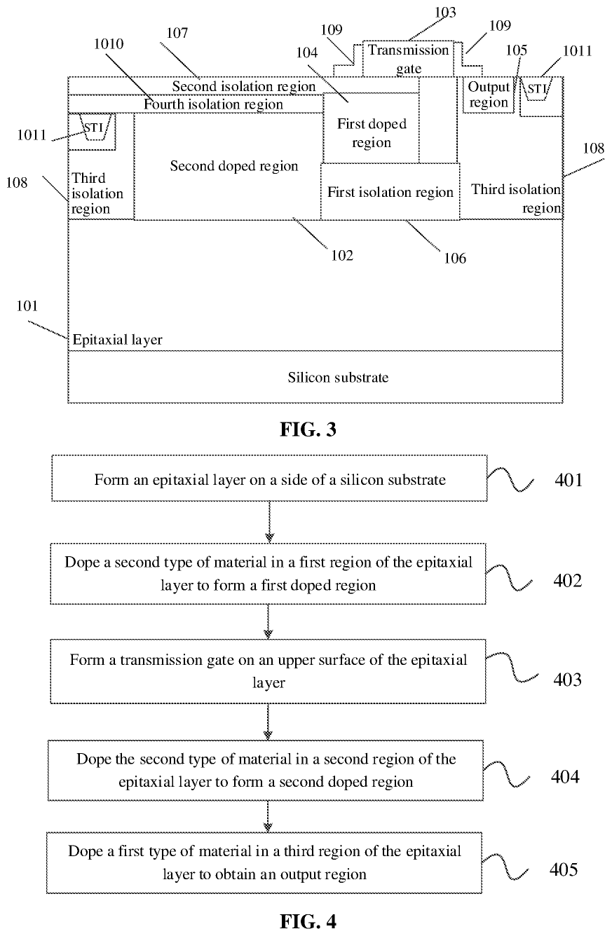

FIG. 3 is a schematic structural diagram of a photodiode according to another embodiment of the present disclosure. As shown in FIG. 3, based on the above embodiment, the photodiode further includes a first isolation region 106.

The first isolation region 106 is disposed below the first region. The first isolation region 106 is doped with the first type of material.

Preferably, the first isolation region 106 is connected to both the and the second doped region. By disposing the first isolation region 106 below the first doped region 102, the photo-generated electrons in the second doped region can be prevented from entering the first doped region.

Preferably, based on the above embodiments, the photodiode further includes a second isolation region 107.

The second isolation region 107 is disposed above the second doped region 104 and the first doped region 102. The second isolation region 107 is doped with the first type of material.

The one side of the transmission gate is connected to the first doped region 102 through the second isolation region 107.

By disposing the second isolation region 107 between the first doped region 102 and the transmission gate, a threshold of the transmission gate can be adjusted. The threshold includes a value of a voltage applied to the transmission gate, that is used for transferring the photo-generated electrons in the second doped region 104 to the output region 105. As described above, in the case that the transmission gate is powered off, a small part of the photo-generated electrons may be injected back into the second doped region 104. However, in this embodiment, the first doped region 102 is disposed between the second doped region 104 and the transmission gate, and the concentration of the second type of material in the first doped region is higher than the concentration of the second type of material in the second doped region, so that the photo-generated electrons can be prevented from being injected back into the second doped region 104 in the case of the transmission gate being powered off, thereby achieving the unidirectional transfer of the photo-generated electrons, that is, the photo-generated electrons are transferred from the second doped region 104 to the output region 105.

Preferably, the second type of material and the first type of material in the above embodiments are respectively different types of semiconductor materials. The semiconductor materials include a P-type semiconductor material and an N-type semiconductor material. The first type of material may be any one of the P-type semiconductor material and the N-type semiconductor material. The second type of material may be the other one of the P-type semiconductor material and the N-type semiconductor material. For example, the P-type semiconductor material may be an ion or a compound of any one element in groups III and II. The N-type semiconductor material may be an ion or a compound of any one element in a group V. It should be noted that, in this embodiment, different elements or the same element may be used for different regions. For example, the first region, the second region and the third region are doped with the second type of material using different elements or the same element. In addition, the fourth isolation region, the second isolation region 107 and the first isolation region 106 are doped with the first type of material using different elements or the same element.

Further, based on the above embodiments, the photodiode further includes a third isolation region 108.

The third isolation region 108 is disposed in a fourth region of the epitaxial layer 101. The third isolation region 108 is doped with the first type of material. The output region 105 is disposed in the third isolation region 108. That is, the fourth region is disposed in a peripheral region of the output region 105, where the peripheral region is disposed in the epitaxial layer 101. The third isolation region 108 is provided with a shallow trench isolation region STI1011. The shallow trench isolation region is used to isolate adjacent pixel units from each other.

In this embodiment, by disposing the third isolation region 108 on the periphery of the output region 105, the output region 105 can be isolated from the second doped region.

Preferably, the third isolation region 108 is not directly connected to the first doped region 102. In this way, the transmission gate 103 functions as a switch between the first doped region 102 and the output region 105.

Optionally, based on the above embodiments, the first isolation region 106 is connected to both the and the second doped region 104.

In this embodiment, the first isolation region 106 is connected to both the and the second doped region 104, so that the photo-generated electrons can be prevented from entering the output region 105 from the second doped region 104 via a channel between the second doped region 104 and the output region 105.

Further, based on the above embodiments, the photodiode further includes a sidewall 109 and a fourth isolation region 1010. The sidewall is disposed on a side surface of the transmission gate. The fourth isolation region is disposed between the second isolation region 107 and the second doped region 104. The fourth isolation region is doped with the first type of material.

A photodiode is further provided according to another embodiment of the present disclosure. In the photodiode, two sides of the second doped region 102 are each provided with the first doped region 104, the first isolation region 106, the output region 105, and the third isolation region 108 in a mirrored manner.

FIG. 4 is a schematic flowchart of a photodiode manufacturing method according to an embodiment of the present disclosure. As shown in FIG. 4, the photodiode manufacturing method includes the following steps 401 to 405.

In step 401, an epitaxial layer is formed on a side of a silicon substrate.

In this embodiment, the epitaxial layer is doped with a first type of material. The first type of material for doping in this embodiment is a P-type semiconductor material or an N-type semiconductor material.

For example, the epitaxial layer is prepared on the silicon substrate, and the P-type material is doped during the process of preparing the epitaxial layer. A thickness of the obtained P-type epitaxial layer is at least 15 um. A concentration of the P-type material in the P-type epitaxial layer is 5e13 cm³.

In step 402, a second type of material is doped in a first region of the epitaxial layer to form a first doped region.

It should be noted that, the second type of material and the first type of material in this embodiment are respectively different types of semiconductor materials. The semiconductor materials include the P-type semiconductor material and the N-type semiconductor material. The first type of material may be any one of the P-type semiconductor material and the N-type semiconductor material. The second type of material may be the other one of the P-type semiconductor material and the N-type semiconductor material. For example, the P-type semiconductor material may be an ion or a compound of any one element in groups III and II. The N-type semiconductor material may be an ion or a compound of any one element in a group V. It should be noted that, in this embodiment, different regions, for example, the first region, the second region and the third region may be doped with the second type of material using different elements or the same element. In addition, different regions may be doped with the first type of material doping using different elements or the same element.

In step 403, a transmission gate is formed on an upper surface of the epitaxial layer.

In this embodiment, the transmission gate is connected to the first doped region.

For example, a polysilicon gate is firstly formed on the upper surface of the epitaxial layer, and the polysilicon gate is etched to form the transmission gate.

In step 404, the second type of material is doped in a second region of the epitaxial layer to form a second doped region.

In this embodiment, the second doped region is connected to the first doped region.

It should be noted that, a concentration of the second type of material in the first doped region is higher than a concentration of the second type of material in the second doped region.

For example, the second type of material is doped in the first region of the epitaxial layer by an implantation process, and the second type of material is doped in the second region of the epitaxial layer by an implantation process, which are implemented by performing the following operations. Firstly, arsenic, as the second type of material, is implanted into the second region with an implantation dose of dose=3e11cm⁻² and an implantation energy of energy=50 Kev. Next, after the transmission gate is formed, the arsenic as the second type of material is implanted into the first region with an implantation dose of 2.6e11cm⁻² and an implantation energy of 125 Kev.

In step 405, the first type of material is doped in a third region of the epitaxial layer to obtain an output region.

In this embodiment, one side of the transmission gate is connected to the output region 105, and the other side of the transmission gate is connected to the first doped region.

For example, in this embodiment, the first type of material is doped in the third region of the epitaxial layer by an implantation process. For example, phosphorus P, as the first type of material, is implanted with an implantation dose of 6e13cm⁻² and an implantation energy of 14 Kev.

When the photodiode receives a light, the light enters the epitaxial layer 101 to generate photo-generated electrons. The second doped region 104 attracts the photo-generated electrons, so that the photo-generated electrons are attracted into the second doped region 104. Next, the transmission gate is powered on, so that the photo-generated electrons in the second doped region 104 are transmitted to the output region 105 via the first doped region 102. As described above, if the transmission gate is powered off, part of the photo-generated electrons may flow back to the second doped region 104. By disposing the first doped region 102 between the second doped region 104 and the output region 105, the photo-generated electrons can be stored in the first doped region 102, which prevents the photo-generated electrons from flowing back to the second doped region 104, improves a photoelectric conversion effect of the photodiode, and further improves a processing efficiency of the photodiode.

In this embodiment, the photodiode manufacturing method includes: forming an epitaxial layer on a side of a silicon substrate, where the epitaxial layer is doped with a first type of material; doping a second type of material in a first region of the epitaxial layer to form a first doped region; forming a transmission gate on an upper surface of the epitaxial layer, where one side of the transmission gate is connected to the first doped region; doping the second type of material in a second region of the epitaxial layer to form a second doped region, where the second doped region is connected to the first doped region; and doping the second type of material in a third region of the epitaxial layer to obtain an output region, where the other side of the transmission gate is connected to the output region. With this method, in the case that the transmission gate is powered off, the photo-generated electrons released from the inversion layer between the first doped region and the output region can be stored in the first doped region disposed between the second doped region and the transmission gate before flowing back to the second doped region, which prevents the released photo-generated electrons from flowing back to the second doped region, avoids the influence on the photo-generated electrons generated in the next photoelectric conversion process, and further improves the photoelectric conversion effect of the photodiode.

It should be noted that, an order of implementing the photodiode manufacturing method is not limited to the order of the above steps. For example, in an implementation of the photodiode manufacturing method, step 403 is performed before step 402. In another implementation of the photodiode manufacturing method, step 404 is performed before step 402 and step 403. These are merely exemplary and do not limit the scope of the present disclosure.

A photodiode is further provided according to another embodiment of the present disclosure. Based on the above embodiment, before step 402 is performed, the method further includes: doping the first type of material below the first region to form a first isolation region 106.

Preferably, the first type of material is doped below the first region by performing multiple implantations, to form the first isolation region 106. For example, boron B, as the first type of material, is implanted twice. The boron B as the first type of material is implanted for the first time with an implantation dose of 6e11cm⁻² and an implantation energy of 1450 Kev, and is implanted for the second time with an implantation dose of 6e11cm⁻² and an implantation energy of 1100 Kev.

By disposing the first isolation region 106 below the first doped region, the photo-generated electrons in the second doped region can be prevented from entering the first doped region.

A photodiode is further provided according to another embodiment of the present disclosure. Based on the above embodiments, before the transmission gate is formed on the upper surface of the epitaxial layer, the photodiode manufacturing method further includes: doping the first type of material above the second doped region 104 and the first doped region to form a second isolation region.

The other side of the transmission gate is connected to the first doped region through the second isolation region 107.

By disposing the second isolation region 107 between the first doped region and the transmission gate, a threshold of the transmission gate can be adjusted. The threshold includes a value of a voltage applied to the transmission gate, that is used for transferring the photo-generated electrons in the second doped region to the output region. As described above, in the case that the transmission gate is powered off, a small part of the photo-generated electrons may be injected back into the second doped region. However, in this embodiment, the first doped region is disposed between the second doped region and the transmission gate, and the concentration of the second type of material in the first doped region is higher than the concentration of the second type of material in the second doped region, so that the photo-generated electrons can be prevented from being injected back into the second doped region in the case of the transmission gate being powered off, thereby achieving the unidirectional transfer of the photo-generated electrons, that is, the photo-generated electrons are transferred from the second doped region to the output region.

It should be noted that, the doping in the above embodiments may be implemented by an implantation process.

Preferably, at least half of a lower surface of the transmission gate is connected to the first doped region.

An overlapping region exists between the first doped region and the second doped region.

In this embodiment, the overlapping region exists between the first doped region and the second doped region. As described above, in the case that the transmission gate is powered off, a small part of the photo-generated electrons may be injected back into the second doped region. However, in this embodiment, the first doped region is disposed between the second doped region and the transmission gate, and the concentration of the second type of material in the overlapping region is higher than the concentration of the second type of material in the first doped region, so that the photo-generated electrons can be stored in the overlapping region, preventing the photo-generated electrons from being injected back into the second doped region 104 in the case of the transmission gate being powered off, thereby achieving the unidirectional transfer of the photo-generated electrons, that is, the photo-generated electrons are transferred from the second doped region 104 to the output region 105.

A photodiode is further provided according to another embodiment of the present disclosure. Based on the above embodiments, before the second type of material is doped in the first region of the epitaxial layer to form the first doped region, the photodiode manufacturing method further includes: doping the first type of material in a fourth region of the epitaxial layer to form a third isolation region 108. The output region 105 is disposed in the third isolation region 108.

Preferably, the third isolation region 108 is not directly connected to the first doped region. In this way, the transmission gate 103 functions as a switch between the first doped region 102 and the output region 105.

The process of doping the first type of material in the fourth region of the epitaxial layer to form the third isolation region 108 may be performed by implanting the first type of material in the fourth region at least twice. In two successive implantations, an implantation dose and an implantation energy in a later implantation are respectively smaller than those in a previous implantation.

Preferably, the first isolation region 106 is connected to both the and the second doped region 104.

In this embodiment, the first isolation region 106 is connected to both the and the second doped region 104, so that the photo-generated electrons can be prevented from entering the output region 105 from the second doped region 104 via a channel between the second doped region 104 and the output region 105.

A photodiode is further provided according to another embodiment. Based on the above embodiments, after the transmission gate is formed on the upper surface of the epitaxial layer, the photodiode manufacturing method further includes: forming a sidewall on a side surface of the transmission gate; and doping the first type of material between the second isolation region 107 and the second doped region 104 to obtain a fourth isolation region. The third region is located between the second isolation region 107 and the second doped region 104.

Optionally, based on the above embodiments, the process of forming the transmission gate on the upper surface of the epitaxial layer includes:

forming a polysilicon gate on the upper surface of the epitaxial layer; and

etching the polysilicon gate to form the transmission gate.

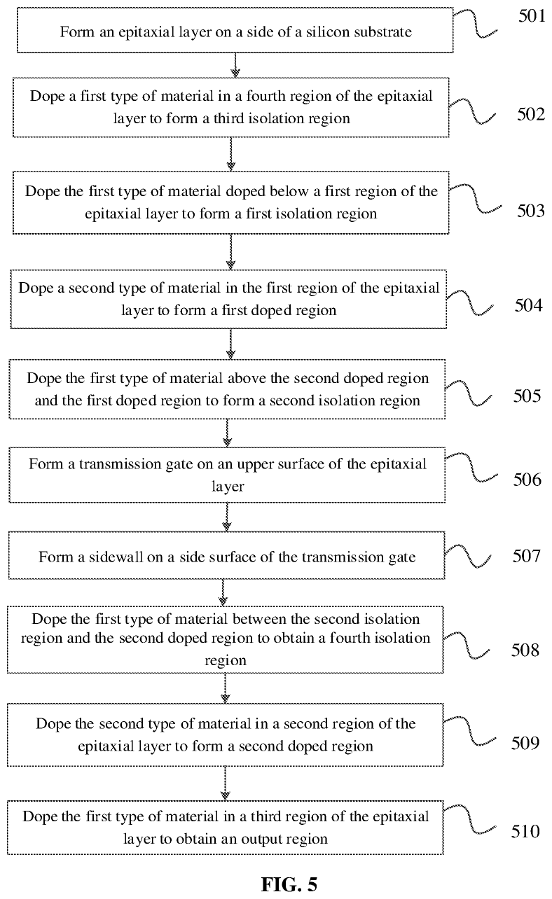

FIG. 5 is a schematic flowchart of a photodiode manufacturing method according to another embodiment of the present disclosure. As shown in FIG. 5, the photodiode manufacturing method includes the following steps 501 to 510.

In step 501, an epitaxial layer is formed on a side of a silicon substrate.

In this embodiment, the epitaxial layer is doped with a first type of material. The first type of material for doping in this embodiment is a P-type semiconductor material or an N-type semiconductor material.

For example, the epitaxial layer is prepared on the silicon substrate, and the P-type material is doped during the process of preparing the epitaxial layer. A thickness of the obtained P-type epitaxial layer is at least 15 um. A concentration of the P-type material in the P-type epitaxial layer is 5e13cm³.

In step 502, a first type of material is doped in a fourth region of the epitaxial layer to form a third isolation region.

In this embodiment, an output region 105 is disposed in the third isolation region 108.

Preferably, the third isolation region 108 is not directly connected to the first doped region.

The process of doping the first type of material in the fourth region of the epitaxial layer to form the third isolation region 108 may be performed at least by implanting the first type of material in the fourth region at least twice. In two successive implantations, an implantation dose and an implantation energy in a later implantation are respectively smaller than those in a previous implantation.

In step 503, the first type of material is doped below a first region of the epitaxial layer to form a first isolation region.

For example, the first type of material is doped below the first region by performing multiple implantations, to form the first isolation region 106. For example, boron B, as the first type of material, is implanted twice. An implantation dose of the first type of material in a first implantation is the same as that in a second implantation. An implantation energy in the first implantation is greater than that in the second implantation. For example, in the case of the boron B being the implanted material, the implantation energy in the first implantation is 1100, and the implantation energy in the second implantation is 900. The first region is a region where the second doped region 104 is formed.

By disposing the first isolation region 106 below the first doped region, the first doped region can be isolated from the epitaxial layer, thereby preventing the photo-generated electrons stored in the first doped region from being transmitted to the epitaxial layer.

In step 504, a second type of material is doped in the first region of the epitaxial layer to form a first doped region.

Preferably, an overlapping region exists between the first doped region and the second doped region 104.

For example, the second type of material is doped in the first region of the epitaxial layer by an implantation process, and the second type of material is doped in a second region of the epitaxial layer by an implantation process, which are implemented by performing the follows operations. Firstly, arsenic, as the second type of material, is implanted into the second region with an implantation dose of dose=2.6e12 and an implantation energy of energy=60. Next, after the transmission gate is formed, the arsenic as the second type of material is implanted into the first region with an implantation dose of 1.6e12 and an implantation energy of 145.

In step 505, the first type of material is doped above the second doped region and the first doped region to form a second isolation region.

In step 506, a transmission gate is formed on an upper surface of the epitaxial layer.

A polysilicon gate is formed on the upper surface of the epitaxial layer, and the polysilicon gate is etched to form the transmission gate.

Preferably, at least half of a lower surface of the transmission gate is connected to the first doped region.

In step 507, a sidewall is formed on a side surface of the transmission gate.

In step 508, the first type of material is doped between the second isolation region and the second doped region to obtain a fourth isolation region.

In step 509, the second type of material is doped in a second region of the epitaxial layer to form a second doped region.

In this embodiment, the second doped region is connected to the first doped region.

Further, the first isolation region 106 is connected to both the and the second doped region.

It should be noted that, a concentration of the second type of material in the first doped region is higher than a concentration of the second type of material in the second doped region.

In step 510, the first type of material is doped in a third region of the epitaxial layer to obtain an output region.

In this embodiment, one side of the transmission gate is connected to the output region 105, and the other side of the transmission gate is connected to the first doped region.

For example, in this embodiment, the first type of material is doped in the third region of the epitaxial layer by an implantation process. For example, phosphorus P, as the first type of material, is implanted with an implantation dose of 6e15 and an implantation energy of 15 KeV.

In this embodiment, in the case that the transmission gate is powered off, the photo-generated electrons released from the inversion layer between the first doped region and the output region are stored in the first doped region disposed between the second doped region and the transmission gate before flowing back to the second doped region, which prevents the released photo-generated electrons from flowing back to the second doped region, avoids the influence on the photo-generated electrons generated in the next photoelectric conversion process, and further improves the photoelectric conversion effect of the photodiode.

It should further be noted that, technical features described in the above embodiments can be combined in any suitable manner in the absence of contradiction. Further, different implementations in the present disclosure can be combined in any manner without departing from the idea of the present disclosure. These combinations should be regarded as contents disclosed in the present disclosure. The present disclosure is not limited to structures described above. The scope of the present disclosure is only defined by the appended claims.

1. A photodiode manufacturing method, comprising:
forming an epitaxial layer on a side of a silicon substrate, wherein the epitaxial layer is doped with a first type of material;
doping a second type of material in a first region of the epitaxial layer to form a first doped region;
forming a transmission gate on an upper surface of the epitaxial layer, wherein one side of the transmission gate is connected to the first doped region;
doping the second type of material in a second region of the epitaxial layer to form a second doped region, wherein the second doped region is connected to the first doped region; and
doping the first type of material in a third region of the epitaxial layer to obtain an output region, wherein the other side of the transmission gate is connected to the output region.

2. The photodiode manufacturing method according to claim 1, wherein before doping the second type of material in the first region of the epitaxial layer to form the first doped region, the method further comprises:
doping the first type of material below the first region to form a first isolation region.

3. The photodiode manufacturing method according to claim 2, wherein before forming the transmission gate on the upper surface of the epitaxial layer, the method further comprises:
doping the first type of material above the second doped region and the first doped region to form a second isolation region,
wherein the one side of the transmission gate is connected to the first doped region through the second isolation region.

4. The photodiode manufacturing method according to claim 1, wherein the second type of material and the first type of material are respectively different types of semiconductor materials, and the semiconductor materials comprise a P-type semiconductor material and an N-type semiconductor material.

5. The photodiode manufacturing method according to claim 4, wherein an overlapping region exists between the first doped region and the second doped region.

6. A photodiode, comprising:
an epitaxial layer disposed on a silicon substrate, wherein the epitaxial layer is doped with a first type of material;
a first doped region disposed in a first region of the epitaxial layer, wherein the first doped region is doped with a second type of material;
a transmission gate disposed on an upper surface of the epitaxial layer, wherein one side of the transmission gate is connected to the first doped region;
a second doped region disposed in a second region of the epitaxial layer, wherein the second doped region is doped with the second type of material, and the second doped region is connected to the first doped region; and
an output region disposed in a third region of the epitaxial layer, wherein the output region is doped with the first type of material, and the other side of the transmission gate is connected to the output region.

7. The photodiode according to claim 6, further comprising:
a first isolation region disposed below the first region, wherein the first isolation region is doped with the first type of material.

8. The photodiode according to claim 7, further comprising:
a second isolation region disposed above the second doped region and the first doped region,
wherein the second isolation region is doped with the first type of material; and
the one side of the transmission gate is connected to the first doped region through the second isolation region.

9. The photodiode according to claim 6, wherein the second type of material and the first type of material are respectively different types of semiconductor materials, and the semiconductor materials comprise a P-type semiconductor material and an N-type semiconductor material.

10. The photodiode according to claim 9, wherein an overlapping region exists between the first doped region and the second doped region.

11. The photodiode manufacturing method according to claim 2, wherein the second type of material and the first type of material are respectively different types of semiconductor materials, and the semiconductor materials comprise a P-type semiconductor material and an N-type semiconductor material.

12. The photodiode manufacturing method according to claim 3, wherein the second type of material and the first type of material are respectively different types of semiconductor materials, and the semiconductor materials comprise a P-type semiconductor material and an N-type semiconductor material.

13. The photodiode according to claim 7, wherein the second type of material and the first type of material are respectively different types of semiconductor materials, and the semiconductor materials comprise a P-type semiconductor material and an N-type semiconductor material.

14. The photodiode according to claim 8, wherein the second type of material and the first type of material are respectively different types of semiconductor materials, and the semiconductor materials comprise a P-type semiconductor material and an N-type semiconductor material.
